(19) United States
(12) Patent Application Publication
(10) Pub. No.: US 2026/0244302 A1
(43) Pub. Date: Aug. 20, 2026

(54) DISPLAY PANEL AND DISPLAY APPARATUS

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Yang ZENG, Beijing (CN); Wei WANG, Beijing (CN); Chang LUO, Beijing (CN); Yi ZHANG, Beijing (CN)

(73) Assignees: Chengdu BOE Optoelectronics Technology Co., Ltd., Chengdu, Sichuan (CN); BOE TECHNOLOGY GROUP CO., LTD., Beijing (CN)

(21) Appl. No.: 19/162,423

(22) PCT Filed: Mar. 14, 2024
(86) PCT No.: PCT/CN2024/081681

§ 371 Date: Sep. 5, 2025

(30) Foreign Application Priority Data
Apr. 26, 2023 (CN) 202310463104.5

(51) Int. Cl. G06F 3/044; G06F 3/041; H10K 59/40

(52) U.S. Cl. CPC G06F 3/0446; G06F 3/0412; G06F 3/0443; H10K 59/40

(57) ABSTRACT

The display panel is provided with a display region and a non-display region located on at least one side of the display region. The display panel is provided with a touch function layer, the touch function layer being provided with a plurality of touch positioning regions distributed in an array and touch capacitor structures located in the touch positioning regions. The touch capacitor structures comprise first-type touch capacitor structures arranged in the whole touch positioning region and second-type touch capacitor structures arranged in partial region of the touch positioning region. The second-type touch capacitor structures comprise first sub-capacitor structures located in the display region and second sub-capacitor structures located in the non-display region, the density of distribution of grid lines in at least partial region of at least one second sub-capacitor structure being greater than the that of grid lines of the first-type touch capacitor structures.

### CROSS-REFERENCE TO RELATED APPLICATIONS

The present disclosure is a U.S. National Stage of International Application No. PCT/CN2024/081681, filed on Mar. 14, 2024, which claims priority to Chinese patent application number 202310463104.5, filed on Apr. 26, 2023, entitled “Display Panel and Display Apparatus”, both of which are incorporated herein by reference in their entireties for all purposes.

### TECHNICAL FIELD

The present disclosure relates to the field of display technology, and in particular to a display panel and a display device.

### BACKGROUND

In the OLED display field, FMLOC (Flexible Multi-Layer On Cell) is increasingly being used. FMLOC technology creates a touch-sensitive unit at the intersection by setting up two intersecting signal channels. Touch detection is determined by detecting changes in the capacitance of the touch-sensitive unit. However, in some cases, the pattern of the touch-sensitive unit is incomplete, resulting in significant performance differences between these incomplete units and those of complete units, which can lead to yield loss or touch failure.

It should be noted that the information disclosed in the above background section is intended only to enhance understanding of the background of the present disclosure and may include information that does not constitute prior art known to those skilled in the art.

### SUMMARY

According to a first aspect of the present disclosure, there is provided a display panel, including a display area and a non-display area located at least to one side of the display area;
where the display panel includes a touch sensing layer, the touch sensing layer includes a plurality of touch positioning areas arranged in an array and touch capacitor structures located within the touch positioning areas; where the touch capacitor structures include a first-type touch capacitor structure disposed throughout the touch positioning areas and a second-type touch capacitor structure disposed within a portion of the touch positioning areas; electrodes of the touch capacitor structures are grid electrodes; and
the second-type touch capacitor structure includes a first sub-capacitor structure located in the display area and a second sub-capacitor structure located in the non-display area; where a distribution density of grid lines of at least partial area of at least one second sub-capacitor structure is greater than a distribution density of grid lines of the first-type touch capacitor structure.

According to an embodiment of the present disclosure, in at least one second-type touch capacitor structure, the distribution density of grid lines in each area of the second sub-capacitor structure is greater than the distribution density of grid lines of the first-type touch capacitor structure.

According to an embodiment of the present disclosure, in the at least one second-type touch capacitor structure, the distribution density of grid lines in each area of the second sub-capacitor structure is 2 to 6 times the distribution density of grid lines of the first-type touch capacitor structure, where the distribution density of grid lines is a total length of grid lines per unit area.

According to an embodiment of the present disclosure, the second-type touch capacitor structure includes a first electrode and a second electrode disposed in a same layer and adjacent to each other, a boundary area is defined between the first electrode and the second electrode; the first electrode includes a first edge portion proximate to the boundary area, and the second electrode includes a second edge portion proximate to the boundary area; and
in at least one second-type touch capacitor structure, a spacing between break lines of at least one of the first edge portion and the second edge portion in the non-display area is smaller than a spacing between the break lines of the at least one of the first edge portion and the second edge portion in the display area.

According to an embodiment of the present disclosure, in the at least one second-type touch capacitor structure, the second-type touch capacitor structure includes break line pairs; the break line pairs include first break lines located at the first edge portion and second break lines located at the second edge portion, the first break lines and the second break lines extend in a same direction and have adjacent ends; and
where a spacing between the break line pairs in the non-display area is smaller than a spacing between the break line pairs in the display area.

According to an embodiment of the present disclosure, in the at least one second-type touch capacitor structure, an average spacing between the break line pairs in the non-display area is 0.4 to 0.6 times an average spacing between the break line pairs in the display area.

According to an embodiment of the present disclosure, the second-type touch capacitor structure includes a first electrode and a second electrode disposed in a same layer and adjacent to each other, a boundary area is defined between the first electrode and the second electrode; the first electrode includes a first edge portion proximate to the boundary area, and the second electrode includes a second edge portion proximate to the boundary area;
in at least one second-type touch capacitor structure, a density of break lines of at least one of the first edge portion and the second edge portion in the non-display area is larger than a density of the break lines of the at least one of the first edge portion and the second edge portion in the display area;
the density of the break lines of the first edge portion in the non-display area refers to a ratio of a number of the break lines of the first edge portion in the non-display area to a length of a portion of the boundary area located in the non-display area;
the density of the break lines of the second edge portion in the non-display area refers to a ratio of a number of the break lines of the second edge portion in the non-display area to the length of the portion of the boundary area located in the non-display area;
the density of the break lines of the first edge portion in the display area refers to a ratio of a number of the break lines of the first edge portion in the display area to a length of a portion of the boundary area located in the display area; and
the density of the break lines of the second edge portion in the display area refers to a ratio of a number of the break lines of the second edge portion in the display area to the length of the portion of the boundary area located in the display area.

According to an embodiment of the present disclosure, the second-type touch capacitor structure includes a first electrode and a second electrode disposed in a same layer and adjacent to each other, a boundary area is defined between the first electrode and the second electrode; the first electrode includes a first edge portion proximate to the boundary area, and the second electrode includes a second edge portion proximate to the boundary area; and
in at least one second-type touch capacitor structure, at least one of the first edge portion and the second edge portion includes a closed line located in the non-display area, and the closed line is connected to ends of at least some of the break lines.

According to an embodiment of the present disclosure, in the at least one second-type touch capacitor structure, both the first edge portion and the second edge portion have closed lines; the closed lines of the first edge portion and the second edge portion are parallel and adjacent to each other.

According to an embodiment of the present disclosure, the second-type touch capacitor structure includes a first electrode and a second electrode disposed in a same layer and adjacent to each other;
in at least one second-type touch capacitor structure, the first electrode includes a main body and at least one side branch connected to the main body, a width of the side branch is smaller than a width of the main body; the side branch of the first electrode is disposed adjacent to the second electrode, and the side branch of the first electrode is located in the non-display area; and/or the second electrode includes a main body and at least one side branch connected to the main body, a width of the side branch is smaller than a width of the main body; the side branch of the second electrode is disposed adjacent to the first electrode, and the side branch of the second electrode is located in the non-display area.

According to an embodiment of the present disclosure, in the at least one second-type touch capacitor structure, the first electrode includes multiple side branches, and the second electrode includes multiple side branches;
the side branches of the first electrode and the side branches of the second electrode are disposed alternately and adjacently.

According to an embodiment of the present disclosure, the distribution density of the grid lines of the second sub-capacitor structure is greater than the distribution density of the grid lines of the first-type touch capacitor structure.

According to an embodiment of the present disclosure, in the at least one second-type touch capacitor structure, the side branch includes a side branch main line and multiple break lines connected to the side branch main line.

According to an embodiment of the present disclosure, the touch sensing layer is provided with a plurality of first touch signal channels arranged sequentially along a first direction and a plurality of second touch signal channels arranged sequentially along a second direction, the first direction and the second direction is arranged intersecting;
one of the first touch signal channels and one of the second touch signal channels pass through any touch positioning area; the touch capacitor structure includes a first electrode located in the first touch signal channel and a second electrode located in the second touch signal channel; the first electrode and the second electrode are both grid electrodes composed of grid lines and are provided in a same layer.

According to an embodiment of the present disclosure, at least one of the first touch signal channels and the second touch signal channels includes a channel body and an auxiliary electrode, the auxiliary electrode is surrounded by the channel body and separated from the channel body.

According to an embodiment of the present disclosure, a distribution density of grid lines of the first sub-capacitor structure is consistent with the distribution density of the grid lines of the first-type touch capacitor structure.

According to an embodiment of the present disclosure, the non-display area includes at least one of a first non-display area and a second non-display area;
where the first non-display area surrounds the display area; and the second non-display area is partially or completely surrounded by the display area.

According to an embodiment of the present disclosure, the display area has a curved top corner, and the second-type touch capacitor structure includes a first capacitor structure; and the first capacitor structure spans an edge of the curved top corner of the display area.

According to an embodiment of the present disclosure, a via hole is provided in the second non-display area; the second-type touch capacitor structure includes a second capacitor structure at least partially located in the second non-display area; and a second sub-capacitor structure of the second capacitor structure is grid electrodes composed of grid lines.

According to another embodiment of the present disclosure, there is provided a display device including the aforementioned display panel.

It should be understood that the general description above and the detailed description below are merely illustrative and explanatory, and do not limit the scope of the present disclosure.

### BRIEF DESCRIPTION OF THE DRAWINGS

The accompanying drawings herein are incorporated into and constitute a part of the description. They illustrate embodiments consistent with the present disclosure and, together with the description, serve to explain the principles of the present disclosure. It should be understood that the drawings described below represent only some embodiments of the present disclosure. Those skilled in the art can derive other drawings based on these drawings without inventive effort.

FIG. 1 is a top view structural schematic diagram of a display panel in one embodiment of the present disclosure.

FIG. 2 is a partial cross-sectional structural schematic diagram of a display panel in one embodiment of the present disclosure.

FIG. 3 is a top view structural schematic diagram of a touch sensing layer in the display area in one embodiment of the present disclosure.

FIG. 4 is a partial cross-sectional structural schematic diagram of a touch sensing layer at the edge of the display area in one embodiment of the present disclosure.

FIG. 5-1 is a structural schematic diagram of a touch buffer layer formed on the surface of a display backplane in one embodiment of the present disclosure.

FIG. 5-2 is a structural schematic diagram of a first touch conductive layer formed on the surface of the touch buffer layer in one embodiment of the present disclosure.

FIG. 5-3 is a structural schematic diagram of a touch insulating layer formed on the surface of the first touch conductive layer in one embodiment of the present disclosure.

FIG. 5-4 is a structural schematic diagram of a second touch conductive layer formed on the surface of the touch insulating layer in one embodiment of the present disclosure.

FIG. 6 is a structural schematic diagram of a first-type touch capacitor structure in one embodiment of the present disclosure.

FIG. 7 is a structural schematic diagram of a first capacitor structure in one embodiment of the present disclosure.

FIG. 8 is a partial structural schematic diagram of a first capacitor structure in a related art of the present disclosure.

FIG. 9 is a partial structural schematic diagram of a first capacitor structure in one embodiment of the present disclosure.

FIG. 10 is a partial structural schematic diagram of a first capacitor structure in one embodiment of the present disclosure.

FIG. 11 is a partial structural schematic diagram of a first capacitor structure in one embodiment of the present disclosure.

FIG. 12 is a partial structural schematic diagram of a first capacitor structure in one embodiment of the present disclosure.

FIG. 13 is a partial structural schematic diagram of a first capacitor structure in one embodiment of the present disclosure.

FIG. 14 is a partial structural schematic diagram of a second capacitor structure in a related art of the present disclosure.

FIG. 15 is a partial structural schematic diagram of a second capacitor structure in one embodiment of the present disclosure.

FIG. 16 is a partial structural schematic diagram of a second capacitor structure in one embodiment of the present disclosure.

FIG. 17 is a partial structural schematic diagram of a second capacitor structure in one embodiment of the present disclosure.

### EXPLANATION OF REFERENCE NUMBERS

AA, display area; ANDL, pixel electrode layer; Ax, first touch signal channel; AxP, first electrode; BB, non-display area; BB1, first non-display area; BB2, second non-display area; BP, base plate; Buff, inorganic buffer layer; BuffB, touch buffer layer; Bx, second touch signal channel; BxA, bridge; BxB, electrode body; BxP, second electrode; CFL, anti-reflection layer; COML, common electrode layer; D1, first direction; D2, second direction; DBP, display backplane; DRL, drive layer; DUM, auxiliary electrode; EML, emission layer; GI, gate insulating layer; GT, gate layer; HH, via hole; ILD, interlayer dielectric layer ; LD, light-emitting element; MA, first metal block; MB, second metal block; PDC, pixel driving circuit; PDL, pixel definition layer; PIX, sub-pixel; PIXL, pixel layer; PLN, planarization layer; PNL, display panel; SCL, semiconductor layer; SD, source and drain metal layer; TDL, touch insulation layer; TFE, thin film encapsulation layer; TMA, first touch conductive layer; TMB, second touch conductive layer; TS, touch capacitor structure; TSA, first sub-capacitor structure; TSB, second sub-capacitor structure; TSL, touch sensing layer; TSM, second-type touch capacitor structure; TSM1, first capacitor structure; TSM2, second capacitor structure; TSN, first-type touch capacitor structure; TSZ, touch positioning area.

### DETAILED DESCRIPTION

Example embodiments will now be described more fully with reference to the accompanying drawings. However, the example embodiments can be embodied in many forms and should not be construed as limited to the embodiments set forth herein; rather, these embodiments are provided so that this disclosure will be thorough and complete and will fully convey the concepts of the example embodiments to those skilled in the art. Like reference numbers in the figures represent like or similar structures, and detailed descriptions thereof will be omitted. Furthermore, the figures are merely schematic illustrations of the present disclosure and are not necessarily drawn to scale.

While relative terms such as “upper” and “lower” are used herein to describe the relationship of one illustrated component to another, these terms are used herein for convenience only, for example, based on the orientation of the examples depicted in the figures. It should be understood that if the illustrated device were flipped upside down, the component described as “upper” would become the component “lower”. When a structure is referred to as “on” another structure, this may mean that the structure is integrally formed on the other structure, that the structure is “directly” disposed on the other structure, or that the structure is “indirectly” disposed on the other structure via another structure.

The terms “a,” “an,” “the,” “said,” and “at least one” are used to indicate the presence of one or more elements/components; the terms “including” and “having” are used to convey an open-ended, inclusive meaning that additional elements/components/etc. may be present in addition to the listed elements/components/etc. ; the terms “first,” “second,” and “third,” etc., are used solely as labels and do not limit the quantity of their objects.

A structural layer A being located on a side of a structural layer B facing away from the substrate means that the structural layer A is formed on the side of the structural layer B facing away from the substrate. When the structural layer B is a patterned structure, portions of the structural layer A may be located at the same physical height as or lower than the physical height of the structural layer B, with the substrate serving as a height reference.

An embodiment of the present disclosure provides a display panel PNL. Referring to FIG. 1, the display panel PNL includes a display area AA and a non-display area BB located at least to one side of the display area AA. In the display area AA, the display panel PNL is provided with subpixels for display; in the non-display area BB, the display panel PNL may not be provided with subpixels for display, or the subpixels provided may not be used for display.

In one embodiment of the present disclosure, referring to FIG. 1, the non-display area BB may include a first non-display area BB1 surrounding the display area AA and a second non-display area BB2 surrounded by the display area AA. In the example of FIG. 1, there is only one second non-display area BB2. It will be appreciated that in other examples of the present disclosure, there may be multiple second non-display areas BB2.

In the example of FIG. 1, the non-display area BB includes a first non-display area BB1 and a second non-display area BB2, with the second non-display area BB2 being completely surrounded by the display area AA. In other embodiments of the present disclosure, the non-display area BB may include only the first non-display area BB1 or only the second non-display area BB2. In other words, in the embodiments of the present disclosure, the non-display area BB includes at least one of the first non-display area BB1 and the second non-display area BB2. In some other embodiments of the present disclosure, even if the non-display area BB includes a first non-display area BB1 and a second non-display area BB2, at least one second non-display area BB2 may be connected to the first non-display area BB1, such that the display area AA does not completely surround the second non-display area BB2. In other words, in the embodiments of the present disclosure, when the display panel PNL is provided with a second non-display area BB2, the display area AA may completely surround the second non-display area BB2 or partially surround the second non-display area BB2.

In some embodiments of the present disclosure, referring to FIG. 1, at least one corner of the display area AA is curved, such as a rounded corner. In the example of FIG. 1, all corners of the display area AA are rounded. It will be appreciated that in other examples of the present disclosure, some corners of the display area AA may be curved, while others may not be curved, such as right angles; or, alternatively, all corners of the display area AA may not be curved, such as all corners are right angles. In the embodiments of the present disclosure, for convenience, the edges of the curved corners of the display area AA are labeled as curved edges CC.

In some embodiments of the present disclosure, a through hole HH may be provided within the second non-display area BB2 to allow light to pass through the display panel PNL at the through hole HH. In one display device, photosensitive components may be provided on the back side of the display panel PNL. The photosensitive components may correspond one to one with the through holes HH, and the photosensitive components may face the corresponding through holes HH to receive light transmitted through the through holes HH. The photosensitive components may be one or more light sensors, such as a camera, an optical fingerprint recognition chip, a light intensity sensor, etc. In one example, the photosensitive component may be a camera, such as a CCD (charge-coupled device) camera. In other embodiments of the present disclosure, the display device may also be provided with other components at the through hole HH, such as an illumination component, rather than necessarily a photosensitive component.

In one embodiment of the present disclosure, referring to FIG. 1, the through hole HH may be circular or oblong. Of course, in other embodiments of the present disclosure, the through hole HH may also have other shapes, such as a rounded rectangle, a strip, an ellipse, or other feasible shapes.

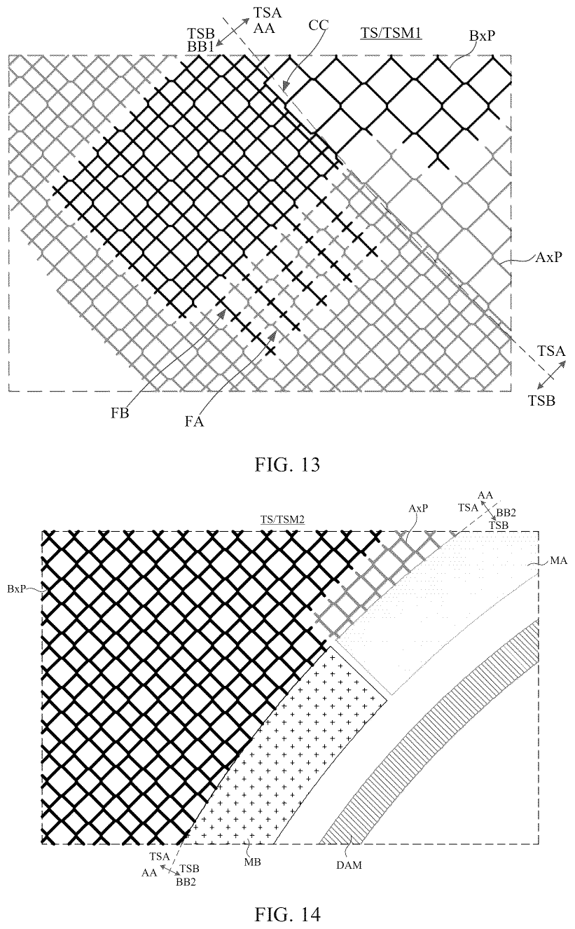

In one embodiment of the present disclosure, as shown in FIG. 14, the second non-display area BB2 includes a through-hole encapsulation area disposed between the through-hole HH and the display area AA to prevent water and oxygen from invading the display area AA through the through-hole HH and to block cracks from extending into the display area AA. In some examples, a barrier structure DAM, such as a partition wall and a crack wall, may be provided within the through-hole encapsulation area. In one example, both the partition wall and the crack wall surround the through-hole HH.

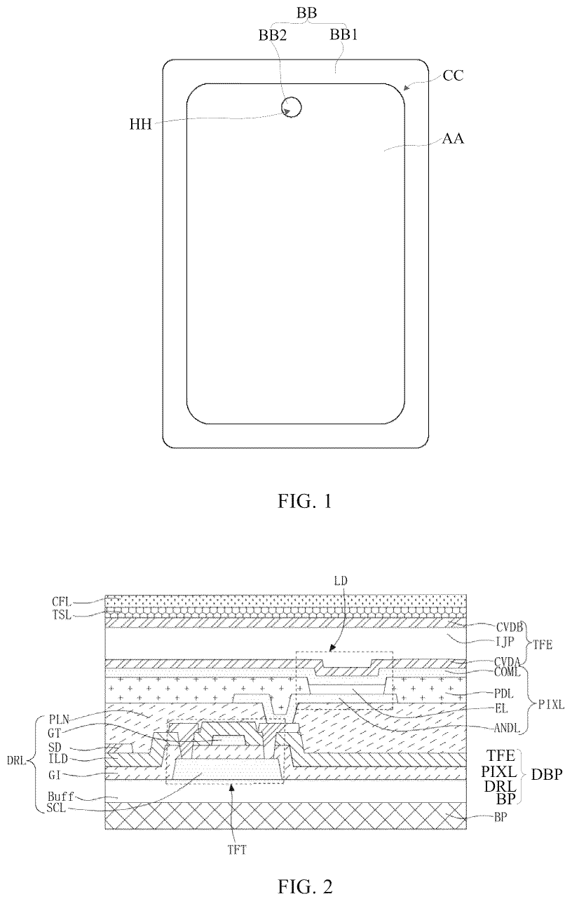

FIG. 2 is a partial cross-sectional structural diagram of the display panel PNL in one embodiment of the present disclosure. As shown in FIG. 2, the display panel PNL includes a display backplane DBP and a touch sensing layer TSL disposed on the light-emitting side of the display backplane DBP. The display backplane DBP is provided with light-emitting elements LD as sub-pixels, and the touch sensing layer TSL is configured to provide the display panel PNL with touch functionality. Thus, the display panel PNL is a touch-enabled display panel.

In one embodiment of the present disclosure, as shown in FIG. 2, the display backplane DBP includes a base plate BP, a drive layer DRL, a pixel layer PIXL, and a thin-film encapsulation layer TFE, stacked in sequence. The pixel layer PIXL is provided with light-emitting elements LD, which serve as subpixels, and the drive layer DRL is provided with pixel drive circuits for driving the subpixels. The touch sensing layer TSL is disposed on a side of the thin-film encapsulation layer TFE facing away from the base plate BP. In this case, the side facing the pixel layer PIXL serves as the light-emitting side of the display backplane DBP.

In some examples, the base plate BP can be made of an inorganic or organic material; of course, it can also be a composite plate formed by stacking an inorganic and organic base plates. For example, in some embodiments of the present disclosure, the material of the base plate BP may be a glass material such as soda-lime glass, quartz glass, and sapphire glass. In other embodiments of the present disclosure, the material of the base plate BP may be polymethyl methacrylate, polyvinyl alcohol, polyvinylphenol, polyethersulfone, polyimide, polyamide, polyacetal, polycarbonate, polyethylene terephthalate, polyethylene naphthalate, or a combination thereof. In other embodiments of the present disclosure, the base plate BP may also be a flexible base plate BP. For example, the material of the base plate BP may include polyimide.

In some examples, in the drive layer DRL, any pixel drive circuit may include a transistor TFT and a storage capacitor. Furthermore, the transistor TFT may be a thin-film transistor, which may be selected from a top-gate thin-film transistor, a bottom-gate thin-film transistor, or a dual-gate thin-film transistor. The material of the active layer of the thin-film transistor may be an amorphous silicon semiconductor material, a low-temperature polycrystalline silicon semiconductor material, a metal oxide semiconductor material, an organic semiconductor material, or other types of semiconductor materials. The thin-film transistor may be an N-type thin-film transistor or a P-type thin-film transistor.

It is understood that any two transistors in the pixel driver circuit may be of the same or different types. For example, in some embodiments, in a pixel driver circuit, some transistors may be N-type transistors and some may be P-type transistors. Furthermore, in other embodiments, in a pixel driver circuit, the materials of the active layers of a part of transistors may be low-temperature polysilicon semiconductor materials, and the materials of the active layers of a part of transistors may be metal oxide semiconductor materials. In some embodiments of the present disclosure, the thin-film transistors are low-temperature polysilicon transistors. In other embodiments of the present disclosure, a part of thin-film transistors are low-temperature polysilicon transistors and a part of thin-film transistors are metal oxide transistors.

In some examples, the drive layer DRL may include a semiconductor layer SCL, a gate insulating layer GI, a gate layer GT, an interlayer dielectric layer ILD, a source/drain metal layer SD, a planarization layer PLN, and the like, stacked between the base plate BP and the pixel layer PIXL. The thin-film transistors and storage capacitors may be formed from film layers such as the semiconductor layer SCL, the gate insulating layer GI, the gate layer GT, the interlayer dielectric layer ILD, and the source/drain metal layer SD. The positional relationship of respective film layers can be determined according to the film layer structure of the thin film transistor. Furthermore, the semiconductor layer SCL can be configured to form the channel region of the transistor, and when necessary, it can also be formed into a partial wiring or conductive structure by conductivization. The gate layer can be configured to form one or more of the gate layer wirings such as the scanning wiring, the reset control wiring, the light emitting control wiring, etc., and can also be configured to form the gate of the transistor, and can also be configured to form part or all of the electrode plates of the storage capacitor. The source and drain metal layer can be configured to form source and drain metal layer wirings such as the data voltage wiring and the power supply voltage wiring, and can also be configured to form part of the electrode plates of the storage capacitor. Of course, in other embodiments of the present disclosure, the drive layer DRL may also include other film layers as needed. For example, it may also include a light shielding layer located between the semiconductor layer SCL and the base plate BP, etc. As needed, any of the aforementioned film layers, such as the semiconductor layer SCL, gate layer GT, and source/drain metal layer SD, can be multi-layered. For example, the drive layer DRL can include two different semiconductor layers SCL, two or three source/drain metal layers SD, or two or three gate layers GT. Accordingly, the number of insulating film layers (such as the gate insulating layer GI, interlayer dielectric layer ILD, and planarization layer PLN) in the drive layer DRL can be adaptively increased or decreased, or new insulating film layers can be added as needed.

In some examples, the drive layer DRL can also include a passivation layer. The passivation layer can be disposed on a surface of the source/drain metal layer SD away from the base plate BP to protect the source/drain metal layer SD.

As an example, referring to FIG. 2, the drive layer DRL can include an inorganic buffer layer Buff, a semiconductor layer SCL, a gate insulating layer GI, a gate layer GT, an interlayer dielectric layer ILD, a source/drain metal layer SD, and a planarization layer PLN, stacked in sequence. The resulting thin-film transistor is a top-gate thin-film transistor.

The pixel layer PIXL can be provided with light-emitting elements electrically connected to the pixel driving circuit. These light-emitting elements can serve as sub-pixels in the display panel. In one example, the light-emitting elements serving as sub-pixels are organic light-emitting diodes (OLEDs). It is understood that in other embodiments of the present disclosure, the sub-pixels can also be other types of light-emitting elements, particularly electroluminescent elements such as QLEDs, PLEDs, Micro LEDs, and Mini LEDs, which are current-driven light-emitting elements.

In some embodiments of the present disclosure, the light-emitting elements in the pixel layer PIXL are thin-film light-emitting elements, which may include two stacked electrodes and a light-emitting functional unit sandwiched between the two electrodes. For example, referring to FIG. 2, the pixel layer PIXL can be provided on a side of the drive layer DRL facing away from the base plate BP, and may include a pixel electrode layer ANDL, a pixel definition layer PDL, an emission layer EML, and a common electrode layer COML, stacked in sequence. The pixel electrode layer ANDL includes multiple pixel electrodes in the display area of the display panel. The pixel definition layer PDL includes multiple through-hole pixel openings in the display area, corresponding to the multiple pixel electrodes one-by-one. Each pixel opening exposes at least a portion of the corresponding pixel electrode. The emission layer (EML) covers at least the pixel electrodes exposed by the pixel definition layer (PDL). The common electrode layer (COML) may cover the emission layer (EML) in the display area. The pixel electrodes and the common electrode layer (COML) provide charge carriers such as electrons and holes to the emission layer (EML), causing the EML to emit light. The portion of the emission layer (EML) located between the pixel electrodes and the common electrode layer (COML) may serve as a light-emitting functional unit. The pixel electrodes, the common electrode layer (COML), and the light-emitting functional unit together form the light-emitting element (LD).

It will be understood that different types of light-emitting elements may use different materials and film layers in the emission layer (EML); correspondingly, the light-emitting functional units of the light-emitting elements may differ. For example, when the light-emitting element is an OLED, the emission layer (EML) may include an organic electroluminescent material layer and may include one or more of a hole injection layer, a hole transport layer, an electron blocking layer, a hole blocking layer, an electron transport layer, and an electron injection layer. When the OLED employs a stacked structure, a charge generation layer may also be provided within the emission layer (EML).

For another example, when the light-emitting element is a QLED, the emission layer (EML) may include a quantum dot material layer and one or more of a hole injection layer, a hole transport layer, an electron blocking layer, a hole blocking layer, an electron transport layer, and an electron injection layer. When the QLED employs a stacked structure, a charge generation layer may also be provided within the emission layer (EML).

Referring to FIG. 2, the display backplane (DBP) may also include a thin-film encapsulation layer (TFE). This thin-film encapsulation layer (TFE) may be provided on the surface of the pixel layer (PIXL) facing away from the base plate (BP) and may include alternating inorganic and organic encapsulation layers. The inorganic encapsulation layer effectively blocks external moisture and oxygen, preventing moisture and oxygen from invading the pixel layer (PIXL) and causing degradation of the materials within the pixel layer (PIXL). In some examples, the edge of the inorganic encapsulation layer may be located in the peripheral region. The organic encapsulation layer is located between two adjacent inorganic encapsulation layers to achieve planarization and reduce stress between the inorganic encapsulation layers. The edge of the organic encapsulation layer may be located between the edge of the display area and the edge of the inorganic encapsulation layer. For example, the thin-film encapsulation layer TFE includes a first inorganic encapsulation layer CVDA, an organic encapsulation layer IJP, and an organic encapsulation layer CVDB, sequentially stacked on a side of the pixel layer PIXL facing away from the base plate BP. Of course, in other embodiments of the present disclosure, the display panel may not include a thin-film encapsulation layer, but may instead employ other methods to encapsulate and protect the pixel layer.

In the aforementioned embodiment, the display backplane DBP includes a base plate BP, a drive layer DRL, a pixel layer PIXL, and a thin-film encapsulation layer TFE, stacked in sequence. It should be understood that the display backplane DBP of the embodiments of the present disclosure is not limited to the aforementioned embodiment, provided that the display backplane DBP can perform display functions.

In one embodiment of the present disclosure, referring to FIG. 2, the display panel PNL may further include an anti-reflection layer CFL located on a side of the touch sensing layer TSL facing away from the display backplane DBP to reduce reflection of ambient light.

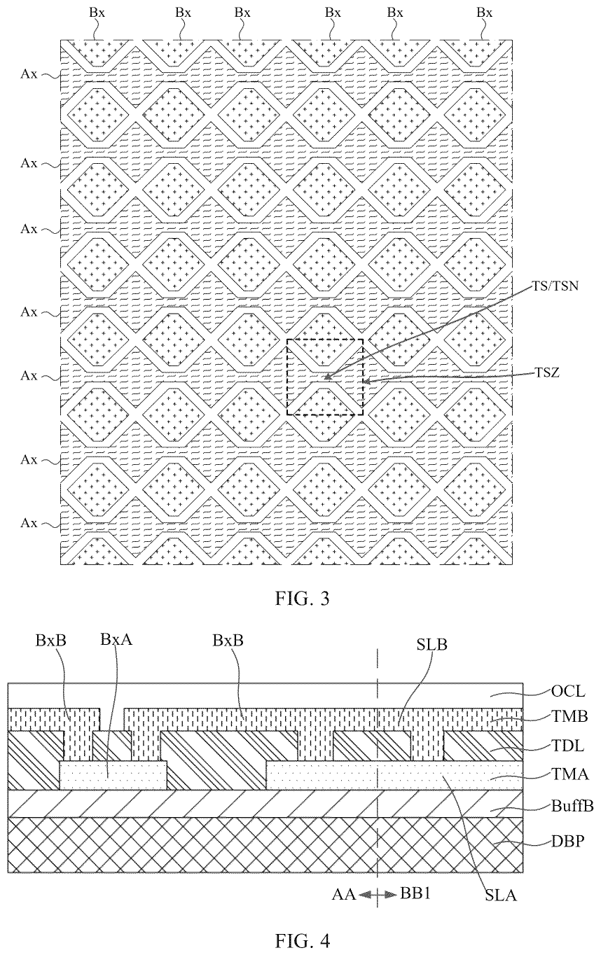

FIG. 3 illustrates a partial structural schematic diagram of the touch sensing layer TSL in the display area AA, in one embodiment of the present disclosure. Referring to FIG. 3, the touch sensing layer TSL has multiple touch signal channels. The touch signal channels include multiple first touch signal channels Ax arranged sequentially along a first direction and multiple second touch signal channels Bx arranged sequentially along a second direction. The first and second directions intersect, for example, being perpendicular to each other. In some embodiments of the present disclosure, one of the first and second directions is the row direction of the display panel PNL (the direction in which the scan lines extend), and the other is the column direction (the direction in which the data voltage lines extend). For example, the first direction is the row direction of the display panel PNL, and the second direction is the column direction of the display panel PNL. In some embodiments of the present disclosure, one of the first touch signal channel Ax and the second touch signal channel Bx is configured to transmit sensing signals, and the other is configured to receive sensing signals. For example, the first touch signal channel Ax can be configured to transmit sensing signals and serves as a signal transmitting channel, while the second touch signal channel Bx can be configured to receive sensing signals and serves as a signal receiving channel.

FIG. 4 is a partial cross-sectional structural schematic diagram of the touch sensing layer TSL at the edge of the display area AA in one embodiment of the present disclosure. As shown in FIG. 4, the touch sensing layer TSL includes a first touch conductive layer TMA, a touch insulating layer TDL, and a second touch conductive layer TMB, which are sequentially stacked on one side of the display backplane DBP. A first touch signal channel Ax can be provided in the second touch conductive layer TMB; a second touch signal channel Bx includes an electrode body BxB and a bridge portion BxA. The electrode body BxB is provided in the second touch conductive layer TMB, and the bridge portion BxA is provided in the first touch conductive layer TMA. Adjacent electrode bodies BxB are connected by the bridge portion. Furthermore, as shown in FIG. 4, the touch sensing layer TSL may also include signal lines provided in the first non-display area BB1. The first touch signal channel Ax and the second touch signal channel Bx are electrically connected to their respective corresponding signal lines. In some examples, the signal lines may include a first signal line SLA disposed on the first touch conductive layer TMA and a second signal line SLB disposed on the second touch conductive layer TMB. The first signal line SLA and the second signal line SLB are connected in parallel through a via hole to reduce signal line impedance.

Alternatively, referring to FIG. 4, in one example, the touch sensing layer TSL may further include a touch buffer layer BuffB located between the display backplane DBP and the first touch conductive layer TMA. The material of the touch buffer layer BuffB may be an inorganic insulating material such as silicon oxide, silicon nitride, or silicon oxynitride.

Alternatively, referring to FIG. 4, in one example, the touch sensing layer TSL may further include a protective layer OCL located on a side of the second touch conductive layer TMB away from the display backplane DBP. The protective layer may be made of resin, optical adhesive, polyimide, or other organic materials.

In the embodiments of the present disclosure, the first touch signal channel Ax and the second touch signal channel Bx may both be grid electrodes. In particular, the first touch signal channel Ax and the electrode body BxB may both be grid electrodes. The grid electrode may include hollow holes and interconnected grid lines (e.g., metal lines or conductive metal oxide lines) that avoid the hollow holes. In the display panel PNL, the orthographic projection of the subpixel on the second touch conductive layer TMB is located within the hollow hole to prevent the grid lines from blocking light emission of the subpixel. It is understood that one hollow hole can cover one subpixel or multiple subpixels. It also can be understood that the shape and size of the hollow hole can be set as needed, and the shapes and sizes of two adjacent hollow holes can be the same or different.

When preparing the touch sensing layer TSL, after obtaining the display backplane DBP, the respective film layers required for the touch sensing layer TSL can be sequentially formed on the surface of the display backplane DBP. For example, the touch sensing layer TSL illustrated in FIG. 4 can be prepared according to the method shown in steps S110 to S150.

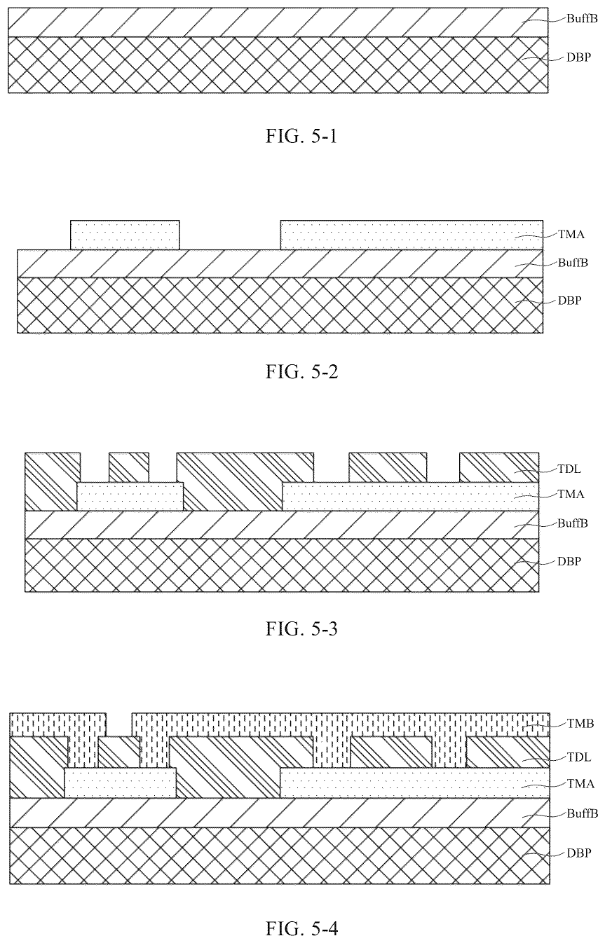

In step S110, see FIG. 5-1, a touch buffer layer BuffB can be formed on a surface of the display backplane DBP.

In step S120, see FIG. 5-2, a first touch conductive layer TMA can be formed on a surface of the touch buffer layer BuffB. The first touch conductive layer TMA includes a bridge portion BxA and a first signal line SLA.

In step S130, see FIG. 5-3, a patterned touch insulation layer TDL can continue to be formed. The touch insulation layer TDL has a via hole that expose the first touch conductive layer TMA. For example, the touch insulation layer TDL has a first via hole that exposes the electrode body BxB and a second via hole that exposes the first signal line SLA.

In step S140, as shown in FIG. 5-4, a second touch conductive layer TMB can continue to be formed. The second touch conductive layer TMB can include a first touch signal channel Ax, an electrode body BxB, and a second signal line SLB. Two adjacent electrode bodies BxB of the second touch signal channel Bx are connected to the bridge portion BxA of the second touch signal channel Bx through a first via hole. The second signal line SLB and the first signal line SLA of the same signal line are connected in parallel through a second via hole.

In step S150, a protective layer OCL is formed to cover the second touch conductive layer TMB.

It will be appreciated that the preparing method of the touch sensing layer TSL can also vary depending on the structure of the touch sensing layer TSL. For example, if the touch sensing layer TSL is an on-board touch sensing layer, the pre-fabricated touch sensing layer TSL can be attached to the surface of the display backplane DBP, rather than fabricating it layer by layer on the surface of the display backplane DBP.

In an embodiment of the present disclosure, referring to FIG. 3, a first touch signal channel Ax and a second touch signal channel Bx define a plurality of touch positioning zones TSZ arranged in an array. Within any of the touch positioning zones TSZ, there is one first touch signal channel Ax and one second touch signal channel Bx. Touch capacitance is formed by the mutual capacitance between the first touch signal channel Ax and the second touch signal channel Bx within the touch positioning zone TSZ. During a touch, the capacitance of the touch capacitor within the touch positioning zone TSZ changes in response to a touching object (e.g., a finger). The driver chip determines the touch location by detecting the change in capacitance (or a parameter related to the capacitance change) of the touch capacitors in different touch positioning zones TSZ. In an embodiment of the present disclosure, the portion of the first touch signal channel Ax within the touch positioning zone TSZ and the portion of the second touch signal channel Bx within the touch positioning zone TSZ are combined as a touch capacitor structure TS. The capacitance of the touch capacitor structure TS is the capacitance of the touch capacitor formed by the first touch signal channel Ax and the second touch signal channel Bx within the touch positioning zone TSZ. Thus, the touch sensing layer TSL of the embodiment of the present disclosure includes an array of touch positioning areas TSZ and touch capacitor structures TS located within the touch positioning areas TSZ.

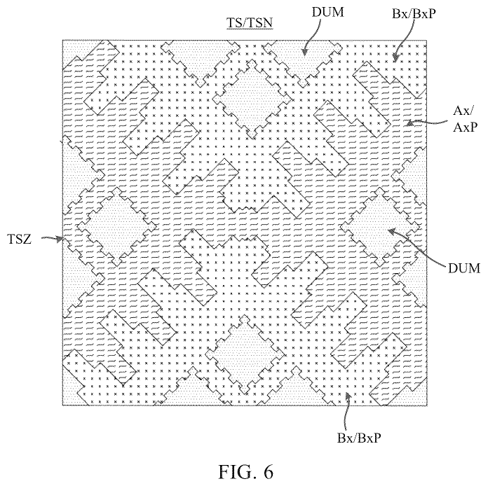

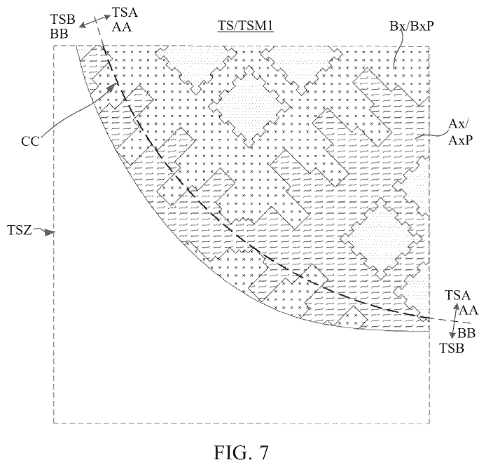

FIG. 6 is a structural schematic diagram of the touch capacitor structure TS in one embodiment of the present disclosure. FIG. 6 only illustrates the structure of the touch capacitor structure TS on the second touch conductive layer TMB. Referring to FIG. 6, the touch capacitor structure TS includes a first electrode AxP and a second electrode BxP disposed adjacent to each other in the same layer. The first electrode AxP and the second electrode BxP are capacitively coupled to form an interdigital capacitor. The first electrode AxP is located in the first touch signal channel Ax, and the second electrode BxP is located in the second touch signal channel Bx. Both the first electrode AxP and the second electrode BxP are grid electrodes composed of grid lines. According to the example in FIG. 4, in this embodiment, the first electrode AxP can be the portion of the first touch signal channel Ax located in the touch positioning zone TSZ, and the first electrode AxP is located in the second touch conductive layer TMB; the second electrode BxP can be an electrode body BxB, which is disposed together with the first electrode AxP in the second touch conductive layer TMB. It is understood that when the touch sensing layer TSL does not adopt the structure illustrated in FIG. 4, the meanings of the first electrode AxP and the second electrode BxP can be modified, so that the first electrode AxP and the second electrode BxP belong to the first touch signal channel Ax and the second touch signal channel Bx, respectively, and both are located in the same touch positioning zone TSZ and are arranged adjacent to each other in the same layer so as to form an interdigital capacitor. It is also understood that the touch capacitor structure TS not only includes the interdigital capacitor formed between the first electrode AxP and the second electrode BxP, but also includes the parallel plate capacitor between the first touch signal channel Ax and the second touch signal channel Bx. For example, the first electrode AxP overlaps with the bridge portion BxA, forming a parallel plate capacitor between the two.

In some examples, as shown in FIG. 6, at least one of the first touch signal channel Ax and the second touch signal channel Bx includes a channel body and an auxiliary electrode DUM. The auxiliary electrode DUM is surrounded by the channel body and separated from the channel body. This reduces the ground capacitance of the first touch signal channel Ax and the second touch signal channel Bx, thereby reducing the load on the driver chip. Furthermore, in the display area AA, the grid pattern of the auxiliary electrode DUM can be the same as that of the first touch signal channel Ax or the second touch signal channel Bx, so that the touch sensing layer TSL has a uniform grid pattern in the display area AA. Furthermore, the auxiliary electrode DUM is disposed on at least one of the first electrode AxP and the second electrode BxP, and thus located on the second touch conductive layer TMB.

FIG. 3 is a top view of a partial structure of the touch sensing layer TSL in the display area AA in one embodiment of the present disclosure. Referring to FIG. 3, the touch capacitor structure TS includes a first type of touch capacitor structure TSN disposed throughout the touch positioning area TSZ. In some cases, the touch capacitor structure TS is not set in the entire touch positioning area TSZ. For example, at the arc-shaped top corner of the display area AA, or near the second non-display area BB2, the touch capacitor structure TS may only be set in the display area AA part of the touch positioning area TSZ, while the non-display area BB part of the touch positioning area TSZ is left vacant. In this case, the layout area of these touch capacitor structures TS is obviously too small and problems are prone to occur. Specifically, if the layout area of the touch capacitor structure TS is too small, the capacitance value of the touch capacitor structure TS will be too small, which will easily be judged as defective during production and cause yield loss of the display panel PNL; if the layout area of the touch capacitor structure TS is too small, the capacitance value change after the touch is too small, which can easily lead to touch failure. In order to solve the above problems, some solutions are provided in the related art. Specifically, an electrode structure is also set in the non-display area BB part of the touch positioning area TSZ to increase the layout area of the touch capacitor structure TS. Due to the location of these touch capacitor structures TS, the newly added electrode structure cannot be set in the non-display area BB part of the entire touch positioning area TSZ, so the touch capacitor structure TS cannot be set in the entire touch positioning area TSZ. In the embodiment of the present disclosure, these touch capacitor structures TS are referred to as the second-type touch capacitor structure TSM. The second-type touch capacitor structure TSM cannot be set in the entire area of the touch positioning area TSZ where it is located. The second-type touch capacitor structure TSM includes a first sub-capacitor structure TSA located in the display area AA and a second sub-capacitor structure TSB located in the non-display area BB. In the embodiment of the present disclosure, the electrode of the touch capacitor structure TS can be a grid electrode, which includes grid lines and hollow holes surrounded by the grid lines. The setting area of the touch capacitor structure TS refers to the area where the grid lines of the touch capacitor structure TS and the hollow holes surrounded by the grid lines are set, rather than just the area where the grid lines are set. For example, the first-type touch capacitor structure TSN disposed throughout the entire touch positioning area TSZ means that the grid lines and surrounding hollow holes of the first-type touch capacitor structure TSN are distributed throughout the entire touch positioning area TSZ; the second-type touch capacitor structure TSM disposed in a portion of the touch positioning area TSZ means that the grid lines and surrounding hollow holes of the second-type touch capacitor structure TSM are distributed in a portion of the touch positioning area TSZ, but not the entire area.

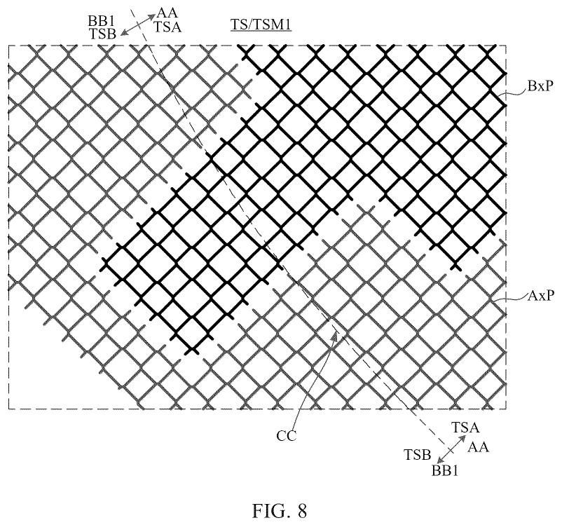

For example, in a related art, referring to FIG. 7, the second-type touch capacitor structure TSM includes a first capacitor structure TSM1. At the arc top corner of the display area AA, the first capacitor structure TSM1 crosses the arc edge CC, resulting in the first capacitor structure TSM1 including a first sub-capacitor structure TSA located on one side of the display area AA and a second sub-capacitor structure TSB located on one side of the first non-display area BB1. In this example, the display panel PNL may also be arc at the arc top corners of the display area AA, limiting the layout space for the second sub-capacitor structure TSB. This means that the display panel PNL cannot provide sufficient space to accommodate the second sub-capacitor structure TSB throughout the remainder of the touch positioning area TSZ. Referring to FIG. 8, the second sub-capacitor structure TSB is located in the first non-display area BB1 and also serves as a grid electrode. The grid pattern of the second sub-capacitor structure TSB is consistent with that of the first sub-capacitor structure TSA and the first-type touch capacitor structure TSN. Compared to not having the second sub-capacitor structure TSB, the first capacitor structure TSM1 improves capacitance value and change amount of the capacitance value. However, in some cases, this still fails to meet requirements. Therefore, the present disclosure provides several optimization solutions to further improve the capacitance value of the first capacitor structure TSM1 and change amount of the capacitance value after a touch.

For another example, in a related art, referring to FIG. 14, the touch capacitor structure TS includes a second capacitor structure TSM2 located near the second non-display area BB2. The second capacitor structure TSM2 includes a first sub-capacitive structure TSA located in the display area AA and a second sub-capacitive structure TSB located in the second non-display area BB2. To increase the self-capacitance of the second capacitor structure TSM2, the second sub-capacitive structure TSB utilizes metal blocks rather than grid lines. Specifically, the second sub-capacitive structure TSB includes a first metal block MA located in the first electrode AxP and a second metal block MB located in the second electrode BxP. In this regard, the present disclosure provides some novel implementations that can compensate for the capacitance value and the change amount of the capacitance value of the second capacitive structure TSM2 without requiring metal blocks in the second non-display area BB2. For example, the second sub-capacitive structure TSB can be a grid electrode composed of grid lines.

Of course, the display panel PNL of the present disclosure may also include the second touch capacitive structures at other locations or for other reasons, and the present disclosure does not exhaustively enumerate these. These second touch capacitive structures TSM include the first sub-capacitive structure TSA located in the display area AA and the second sub-capacitive structure TSB located in the non-display area BB. A part of the touch positioning area TSZ located in the non-display area BB cannot be filled by the second sub-capacitor structures TSB. This results in the layout area of the second-type touch capacitor structure TSM being smaller than the layout area of the first-type touch capacitor structure TSN, which in turn leads to performance differences between the second-type touch capacitor structure TSM and the first-type touch capacitor structure TSN.

The display panel PNL provided in the embodiments of the present disclosure can utilize a grid-like second sub-capacitor structure TSB while minimizing or maintaining the performance difference between the second-type touch capacitor structure TSM and the first-type touch capacitor structure TSN. Specifically, the distribution density of grid lines of at least a portion of at least one second sub-capacitor structure TSB can be greater than that of the first-type touch capacitor structure TSN. This increased distribution density of the grid lines in at least a portion of the second sub-capacitor structure TSB can increase the capacitance of the second sub-capacitor structure TSB, and thus the capacitance of the second-type touch capacitor structure TSM, thereby reducing the risk of the display panel PNL being judged as defective during the manufacturing process. Furthermore, the increased distribution density of the grid lines in at least a portion of the second sub-capacitor structure TSB also helps increase the change amount of the capacitance of the second-type touch capacitor structure TSM after a touch, reducing the risk of touch failure due to a too small change amount of the capacitance. In the embodiments of the present disclosure, unless otherwise specified, the distribution density of the grid lines may refer to the total length of the grid lines per unit area.

Furthermore, in some embodiments of the present disclosure, the grid pattern of the first-type touch capacitor structure TSN can be consistent with the grid pattern of the first sub-capacitor structure TSA to improve the consistency of the grid pattern in the display area AA.

In some embodiments of the present disclosure, the second sub-capacitor structure TSB of at least one second-type touch capacitor structure TSM can employ a global densification strategy to increase the capacitance value of the second-type touch capacitor structure and the change amount of the capacitance value after a touch. For example, in at least one second-type touch capacitor structure TSM, the distribution density of the grid lines in each area of the second sub-capacitor structure TSB is greater than that of the first-type touch capacitor structure TSN.

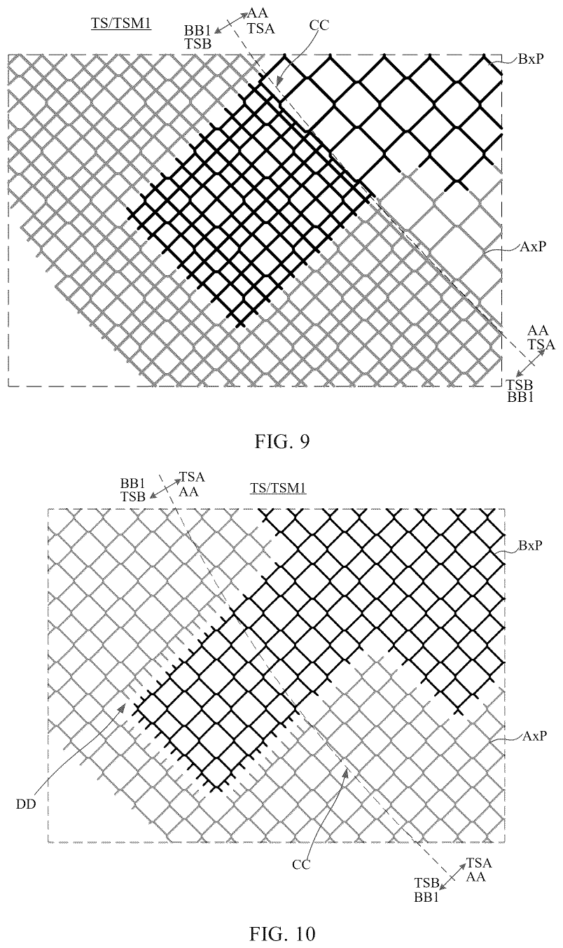

FIG. 9 is a schematic diagram of a partial structure of at least one first capacitor structure TSM1 in one embodiment of the present disclosure. In this embodiment, the first capacitor structure TSM1 includes a first sub-capacitor structure TSA located in the display area AA and a second sub-capacitor structure TSB located in the first non-display area BB1. The distribution density of the grid lines in each area of the second sub-capacitor structure TSB is greater than that of the first-type touch capacitor structure TSN. Furthermore, the distribution density of the grid lines of the first sub-capacitor structure TSA is consistent with that of the first-type touch capacitor structure TSN. In this embodiment, since the first non-display area BB1 is not used for display, the grid lines in the first non-display area BB1 do not need to avoid sub-pixels, which makes it possible to increase the distribution density of grid lines in the non-display area BB.

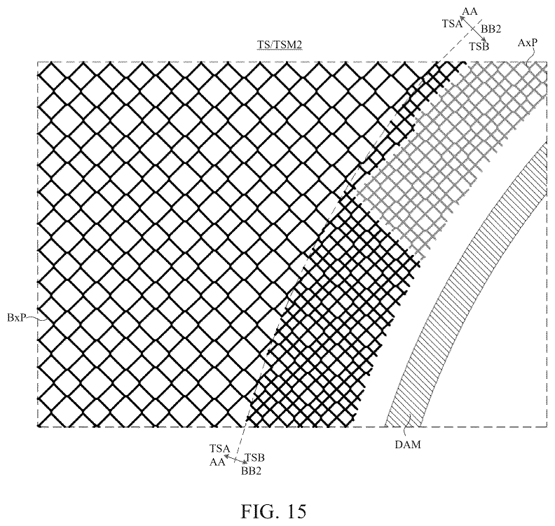

FIG. 15 is a schematic diagram of a partial structure of at least one second capacitor structure TSM2 in one embodiment of the present disclosure. In this embodiment, the second capacitor structure TSM2 includes a first sub-capacitor structure TSA located in the display area AA and a second sub-capacitor structure TSB located in the second non-display area BB2. The distribution density of grid lines in each area of the second sub-capacitor structure TSB is greater than that of the first-type touch capacitor structure TSN. Furthermore, the distribution density of grid lines of the first sub-capacitor structure TSA is consistent with that of the first-type touch capacitor structure TSN. In this embodiment, since the second non-display area BB2 is not used for display, the grid lines in the second non-display area BB2 do not need to avoid sub-pixels, which makes it possible to increase the distribution density of grid lines in the second non-display area BB2.

It will be appreciated that the distribution density of grid lines in each area of the second sub-capacitor structure TSB can be the same or different. In the examples of FIG. 9 and FIG. 15, the distribution density of grid lines in each area of the second sub-capacitor structure TSB is the same to improve the uniformity of the grid pattern of the second sub-capacitor structure TSB.

In one example, referring to FIG. 9 and FIG. 15, the grid lines of the second sub-capacitor structure TSB include first and second grid lines. The grid pattern of the first grid lines is the same as that of the first-type touch capacitor structure TSN. The second grid lines are interspersed between the first gird lines and connected to the first grid lines to increase the grid line distribution density of the second sub-capacitor structure TSB. This facilitates the design and fabrication of the second sub-capacitor structure TSB.

In one example, referring to FIG. 9 and FIG. 15, the first grid lines include first and second strip conductors. The first and second strip conductors extend in different directions and are interconnected. In the second sub-capacitor structure TSB, a first strip auxiliary conductor is provided between any two adjacent parallel first strip conductors, and the first strip auxiliary conductor is arranged parallel to the first strip conductors. A second strip auxiliary conductor is provided between any two adjacent parallel second strip conductors, and the second strip auxiliary conductor is arranged parallel to the second strip conductors. The first strip auxiliary conductors and the second strip auxiliary conductors may constitute the aforementioned second grid lines.

In some examples, the distribution density of grid lines in at least a portion of the second sub-capacitor structure TSB is 2 to 6 times, for example, 4 times, the distribution density of grid lines in the first-type touch capacitor structure TSN.

In some examples, the distribution density of grid lines can be increased by reducing the spacing between two adjacent parallel grid lines. For example, the spacing between two adjacent parallel grid lines in the second sub-capacitor structure TSB is smaller than the spacing between two adjacent parallel grid lines in the first-type touch capacitor structure TSN.

The embodiments of the present disclosure also conducted simulations to verify this global densification strategy. Specifically, the capacitance of the first-type touch capacitor structure TSN is 0.7042 pf, and the capacitance of the first-type touch capacitor structure TSN during touch is 0.6409 pf. Therefore, the change amount of the capacitance of the first-type touch capacitor structure TSN during touch is 0.0633 pf. In one example, when the grid pattern of the second sub-capacitor structure TSB of the first capacitor structure TSM1 and the grid pattern of the first sub-capacitor structure TSA are consistent with the grid pattern of the first-type touch capacitor structure TSN, the capacitance of the first capacitor structure TSM1 is 0.4293 pf, and the capacitance of the first capacitor structure TSM1 during touch is 0.3973 pf. The change amount of the capacitance of the first capacitor structure TSM1 during touch is 0.0320 pf. When the distribution density of grid lines of the second sub-capacitor structure TSB of the first capacitor structure TSM1 is increased, specifically, the distribution density of grid lines of the second sub-capacitor structure TSB is quadrupled (the average spacing between adjacent parallel grid lines is halved), the grid pattern of the first sub-capacitor structure TSA remains unchanged and consistent with the grid pattern of the first-type touch capacitor structure TSN. The capacitance of the first capacitor structure TSM1 is 0.5092 pf, and during touch, the capacitance of the first capacitor structure TSM1 is 0.4728 pf. The change amount of the capacitance of the first capacitor structure TSM1 during touch is 0.0364 pf. This indicates that when the second sub-capacitor structure TSB adopts a global densification strategy, the capacitance of the first capacitor structure TSM1 and the change amount of the capacitance during touch are increased, reducing the performance difference between the first capacitor structure TSM1 and the first-type touch capacitor structure TSN.

In some other embodiments of the present disclosure, the second sub-capacitor structure TSB of at least one second-type touch capacitor structure TSM can employ a strategy of increasing the density of break lines in the boundary area to increase the capacitance value of the second-type touch capacitor structure TSM and change amount of the capacitance during touch.

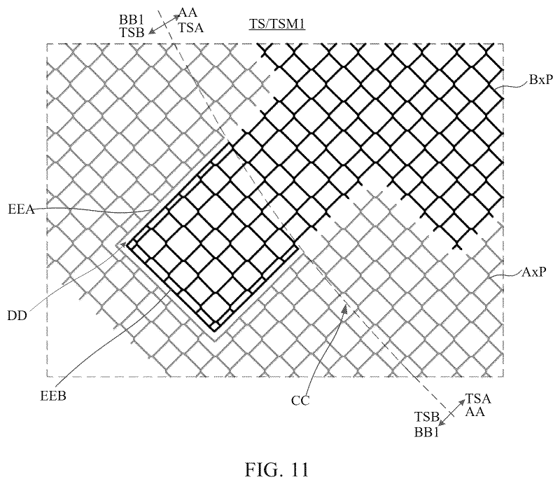

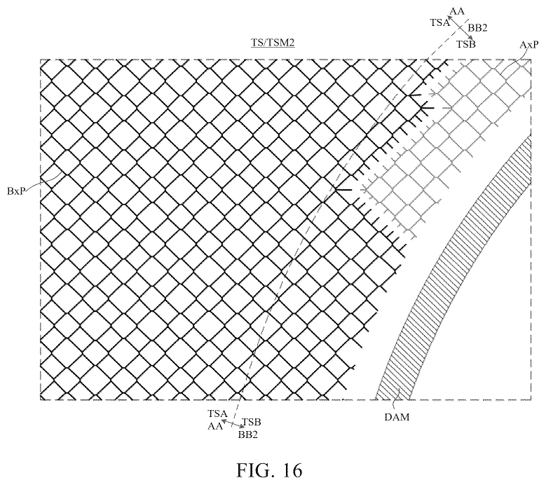

FIG. 10 is a schematic diagram of a partial structure of at least one first capacitor structure TSM1 in one embodiment of the present disclosure. FIG. 16 is a schematic diagram of a partial structure of at least one second capacitor structure TSM2 in one embodiment of the present disclosure. Referring to FIG. 10 and FIG. 16, the second-type touch capacitor structure TSM includes a first electrode AxP and a second electrode BxP disposed adjacent to each other in the same layer. For example, the first electrode AxP and the second electrode BxP are portions of the first and second touch signal channels Ax and Bx on the second touch conductive layer TMB, respectively. A boundary area DD is defined between the first electrode AxP and the second electrode BxP. The first electrode AxP has a first main body and a first edge portion proximate to the boundary area DD, while the second electrode BxP has a second main body and a second edge portion proximate to the boundary area DD. Specifically, the first main body is separated from the boundary area DD by the first edge portion; the second main body is separated from the boundary area DD by the second edge portion.

In at least one of the second-type touch capacitor structures TSM, the density of break lines in at least one of the first edge portion and the second edge portion is greater in the non-display area BB than in the display area AA.

The density of the break lines of the first edge portion in the non-display area BB refers to the ratio of the number of break lines of the first edge portion in the non-display area BB to the length of the portion of the boundary area located in the non-display area BB. The density of the break lines of the second edge portion in the non-display area BB refers to the ratio of the number of break lines of the second edge portion in the non-display area BB to the length of the portion of the boundary area located in the non-display area BB. The density of the break lines of the first edge portion in the display area AA refers to the ratio of the number of break lines of the first edge portion in the display area AA to the length of the portion of the boundary area located in the display area AA. The density of the break lines of the second edge portion in the display area AA refers to the ratio of the number of break lines of the second edge portion in the display area AA to the length of the portion of the boundary area located in the display area AA.

As an example, in at least one of the second-type touch capacitor structures TSM, the spacing of the break lines of at least one of the first edge portion and the second edge portion in the non-display area BB is smaller than the spacing of the break lines in the display area AA. In the embodiment of the present disclosure, a break line is a grid line located adjacent to the boundary area DD and having one end portion unconnected to other grid lines.

In this embodiment, the spacing between break lines located in the first or second edge portion of the non-display area BB is reduced, increasing the density of the break lines and the number of break lines. This enhances the capacitive coupling between the first electrode AxP and the second electrode BxP, thereby increasing the capacitance and capacitance variation of the second-type touch capacitor structure TSM. In this embodiment, the spacing between break lines refers to the distance between two adjacent parallel break lines.

In one embodiment of the present disclosure, referring to FIG. 10 and FIG. 16, in at least one of the second-type touch capacitor structures TSM, the second-type touch capacitor structure TSM includes a break line pair. The break line pair includes a first break line located in the first edge portion and a second break line located in the second edge portion. The first and second break lines extend in the same direction and have adjacent ends. This results in a relatively strong coupling strength between the first and second break lines. The spacing between the break line pairs in the non-display area BB is smaller than the spacing between them in the display area AA.

In one example, referring to FIG. 10 and FIG. 16, the break line pairs include a first break line pair and a second break line pair. The pattern of the first break line pair is consistent with the grid pattern of the first sub-capacitor structure TSA, differing only in that the two break lines of the first break line pair are separated by a boundary area DD. The second break line pair is located in the non-display area BB and inserted between the first break line pairs to increase the density of the break line pairs (reduce the spacing between the break line pairs), thereby increasing the capacitance of the second sub-capacitor structure TSB and improving the coupling capacitance of the second-type touch capacitor structure TSM.

In some examples, in at least one of the second-type touch capacitor structures TSM, the average spacing between the break line pairs in the non-display area BB is 0.4 to 0.6 times the average spacing between the break line pairs in the display area AA.

The embodiments of the present disclosure also simulated and verified this strategy for increasing the density of break lines in the boundary area. Specifically, the capacitance of the first-type touch capacitor structure TSN is 0.7042 pf. During a touch, the capacitance of the first-type touch capacitor structure TSN is 0.6409 pf, and the change amount of the capacitance of the first-type touch capacitor structure TSN is 0.0633 pf. In one example, when the grid pattern of the first capacitor structure TSM1 is consistent with the grid pattern of the first-type touch capacitor structure TSN, the capacitance of the first capacitor structure TSM1 is 0.4293 pf. During a touch, the capacitance of the first capacitor structure TSM1 is 0.3973 pf, and the change amount of the capacitance of the first capacitor structure TSM1 during a touch is 0.0320 pf. When the break lines of the second sub-capacitor structure TSB of the first capacitor structure TSM1 is densified in the boundary area DD, specifically, the spacing of the break lines of the first and second edge portions of the first capacitor structure TSM1 in the first non-display area BB1 is halved compared to that in the display area AA, the capacitance of the first capacitor structure TSM1 is 0.4625 pf, and during touch, the capacitance of the first capacitor structure TSM1 is 0.4282 pf, with a capacitance change of 0.0343 pf. This indicates that when the second sub-capacitor structure TSB employs a densification strategy for the break lines in the boundary area, the capacitance of the first capacitor structure TSM1 and the capacitance change during touch are increased, and the difference from the first-type touch capacitor structure TSN is reduced.

In the aforementioned embodiment, the second-type touch capacitor structure TSM is provided with a break line pair. The break line pair includes a first break line located at the first edge portion and a second break line located at the second edge portion. It is understood that in other examples of the embodiments of the present disclosure, at least one second sub-capacitor structure TSB may include only the first break line, only the second break line, only the first break line of the second break line pair and the first break line pair, only the second break line of the second break line pair and the first break line pair, or at least one second sub-capacitor structure TSB adopts other break line arrangement methods, such that the spacing between the break lines in the second sub-capacitor structure TSB is smaller than the spacing between the break lines in the first sub-capacitor structure TSA.

In the aforementioned embodiments, the grid pattern of the first main body in the non-display area BB and the grid pattern of the second main body in the non-display area BB may be the same as the grid pattern of the first sub-capacitor structure TSA. It is understood that in some other embodiments of the present disclosure, at least one of the grid pattern of the first main body in the non-display area BB and the grid pattern of the second main body in the non-display area BB may differ from the grid pattern of the first sub-capacitor structure TSA. For example, the grid pattern of the first main body in the non-display area BB and the grid pattern of the second main body in the non-display area BB may be the same, and the grid line distribution density is greater than that of the first sub-capacitor structure TSA.

In some other embodiments of the present disclosure, the second sub-capacitor structure TSB of at least one second-type touch capacitor structure TSM may employ a strategy of enclosing break lines in the boundary area to increase the capacitance of the touch capacitor formed by the second-type touch capacitor structure TSM and the change amount of the capacitance during touch.

In these embodiments, in at least one of the second-type touch capacitor structure TSM, at least one of the first edge portion and the second edge portion includes a closed line located in the non-display area BB, and the closed line is connected to the ends of at least some of the break lines. This increases the capacitance of the second-type touch capacitor structure TSM.

In one embodiment of the present disclosure, in at least one of the second-type touch capacitor structures TSM, both the first edge portion and the second edge portion are provided with a closed line. The closed line of the first edge portion and the closed line of the second edge portion are arranged parallel and adjacent to each other. This allows capacitive coupling between the closed line of the first edge portion and the closed line of the second edge portion, thereby significantly increasing the capacitance of the second-type touch capacitor structure TSM.

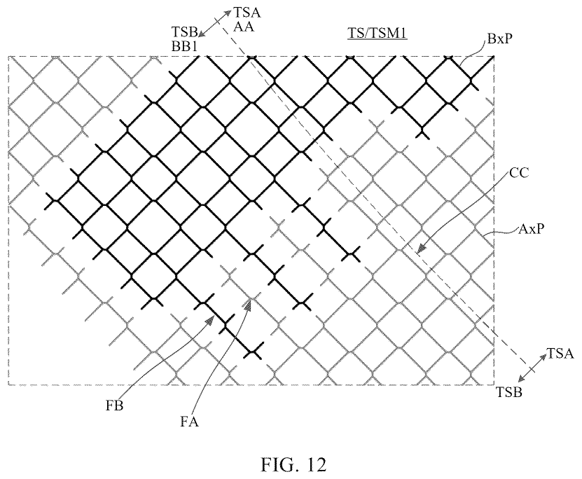

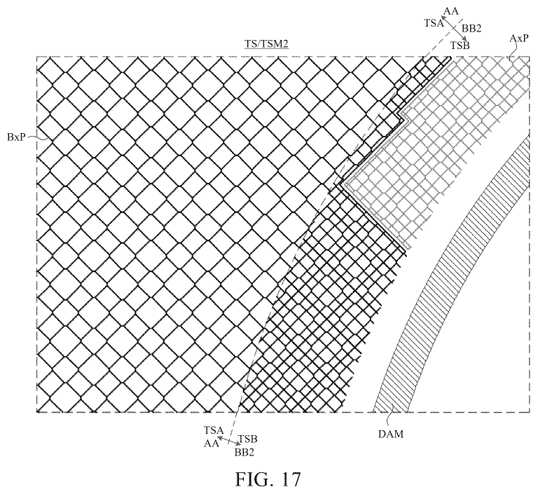

FIG. 11 is a schematic diagram of a partial structure of at least one first capacitor structure TSM1 in one embodiment of the present disclosure. FIG. 17 is a schematic diagram of a partial structure of at least one first capacitor structure TSM1 in one embodiment of the present disclosure. Referring to FIG. 11 and FIG. 17, the first edge portion is provided with a first edge line EEA in the non-display area BB. This first edge line EEA connects to the end of each break line of the first edge portion in the non-display area BB, thereby closing the end of each break line of the first edge portion in the non-display area BB. The second edge portion is provided with a second edge line EEB in the non-display area BB. This second edge line EEB connects to the end of each break line of the second edge portion in the non-display area BB, thereby enclosing the end of each break line of the second edge portion in the non-display area BB. Thus, the ends of the break lines in the first and second edge portions in the non-display area BB are connected to the closed line. Therefore, these break lines are no longer “break lines” in the conventional sense, but rather closed break lines, with the end adjacent to the boundary area DD connected to the closed line and the other end connected to other grid lines. From a dimensional perspective, the length of the closed break line can be smaller than the length of the adjacent grid lines. Specifically, the size of the hollow holes enclosed by the closed line and the break line is smaller than the hollow holes in the first or second main body. It should be understood that in the embodiments of the present disclosure, both the break line and the closed line are types of grid lines of the grid electrode, with specific positions and shapes.

In this example, the first and second closed lines are adjacent and on the same layer, allowing for strong capacitive coupling between them. Compared to the capacitive coupling between the break line pairs, the capacitive coupling between the first and second closed lines has a longer coupling length, resulting in a greater capacitance value. This significantly increases the capacitance of the second-type touch capacitor structure TSM. Furthermore, the arrangement of the first and second closed lines increases the total length of the grid lines in the second sub-capacitor structure TSB, which helps increase the change amount of the capacitance during touch.

The embodiments of the present disclosure also conducted simulations to verify this strategy of blocking break lines in the boundary area. Specifically, the capacitance of the touch capacitor of the first-type touch capacitor structure TSN is 0.7042 pf. During touch, the capacitance of the touch capacitor of the first-type touch capacitor structure TSN is 0.6409 pf, and the change amount of the capacitance of the touch capacitor of the first-type touch capacitor structure TSN is 0.0633 pf. In one example, the grid patterns of the second sub-capacitor structure TSB and the first sub-capacitor structure TSA of the first capacitive structure TSM1 are consistent with the grid pattern of the first touch capacitive structure TSN. The capacitance of the first capacitive structure TSM1 is 0.4293 pf. During a touch, the capacitance of the first capacitive structure TSM1 is 0.3973 pf, and the change amount of the capacitance of the first capacitive structure TSM1 is 0.0320 pf. In another example, the first capacitive structure TSM1 is provided with both a first closed line and a second closed line, and the grid pattern of the remaining grid lines of the first capacitive structure TSM1 is consistent with the grid pattern of the first touch capacitive structure TSN. The capacitance of the first capacitive structure TSM1 is 0.5530 pf. During a touch, the capacitance of the first capacitive structure TSM1 is 0.5174 pf, and the change amount of the capacitance of the first capacitive structure TSM1 is 0.0356 pf. As can be seen, when the second sub-capacitor structure TSB adopts a strategy of enclosing break lines in the boundary area, the capacitance value of the second-type touch capacitor structure TSM and the change amount of the capacitance during touch can be increased, and the difference from the first-type touch capacitor structure TSN can be reduced.

In the above embodiment, the second sub-capacitor structure TSB includes both a first closed line and a second closed line in the non-display area BB. It is understood that in other embodiments of the present disclosure, the second sub-capacitor structure TSB may include only the first closed line or only the second closed line, or the first closed line may only partially enclose the first break line in the non-display area BB, or the second closed line may only partially enclose the second break line in the non-display area BB, or closed lines may be arranged in other ways so that at least a portion of the break lines are enclosed by the closed lines. In the embodiments of the present disclosure, “a break line enclosed by a closed line” means that the end of the break line is connected to the closed line, and the closed line is connected to the ends of at least two break lines.

In the aforementioned embodiments, in at least one second-type touch capacitor structure TSM, the break lines enclosed by the first and second closed lines are arranged in pairs, and the paired break lines can form a break line pair. It is understood that in some other embodiments of the present disclosure, in at least one second-type touch capacitor structure TSM, at least part of the break lines enclosed by the first and second closed lines may not be arranged in pairs. For example, a part of the enclosed break lines or all of the enclosed break lines cannot find a paired break line.

In the embodiment illustrated in FIG. 11, in at least one second-type touch capacitor structure TSM, the grid pattern of the grid lines of the second sub-capacitor structure TSB, excluding the closed lines, can be the same as the grid pattern of the first-type touch capacitor structure TSN. It is understood that in some other embodiments of the present disclosure, in at least one second-type touch capacitor structure TSM, the distribution density of the grid lines of the second sub-capacitor structure TSB, excluding the closed lines, can be greater than the distribution density of the grid lines of the first-type touch capacitor structure TSN. For example, in the example of FIG. 17, in the second-type touch capacitor structure TSM, the second sub-capacitor structure TSB employs both a strategy of enclosing break lines in the boundary area and a global densification strategy.

In some other embodiments of the present disclosure, the second sub-capacitor structure TSB of at least one second-type touch capacitor structure TSM may employ a strategy of increasing side branches to increase the capacitance of the second-type touch capacitor structure TSM.

In this embodiment, the second-type touch capacitor structure TSM includes a first electrode AxP and a second electrode BxP that are arranged in the same layer and are adjacent to each other. In at least one of the second-type touch capacitor structures TSM, the first electrode AxP includes a main body and at least one side branch connected to the main body, and the width of the side branch is smaller than the width of the main body. The side branch of the first electrode AxP is adjacent to the second electrode BxP, and the side branch of the first electrode AxP is located in the non-display area BB; and/or, the second electrode BxP includes a main body and at least one side branch connected to the main body, and the width of the side branch is smaller than the width of the main body; the side branch of the second electrode BxP is adjacent to the first electrode AxP, and the side branch of the second electrode BxP is located in the non-display area BB. In this embodiment, by adding side branches to at least one of the first electrode AxP and the second electrode BxP in the non-display area BB, the length of the boundary area DD between the first electrode AxP and the second electrode BxP can be increased, thereby increasing the coupling capacitance between the first electrode AxP and the second electrode BxP, and improving the capacitance of the second-type touch capacitor structure TSM.

In some examples, in at least one of the second-type touch capacitor structures TSM, the first electrode AxP includes multiple side branches, and the second electrode BxP includes multiple side branches. The side branches of the first electrode AxP and the side branches of the second electrode BxP are arranged alternately and adjacently. In this way, the multiple side branches of the first electrode AxP and the multiple side branches of the second electrode BxP are arranged with interdigital coupling, providing greater coupling capacitance within a smaller coupling area, and significantly improving the capacitance of the second-type touch capacitor structure TSM.

In one embodiment of the present disclosure, referring to FIG. 12 and FIG. 13, in at least one second-type touch capacitor structure TSM, at least one of the first electrode AxP and the second electrode BxP may include a main body and a side branch. The side branch is narrower than the main body and extends toward the opposite electrode. For example, the side branch FA of the first electrode AxP extends toward the second electrode BxP, and the side branch FB of the second electrode BxP extends toward the first electrode AxP. This can increase the coupling length between the first electrode AxP and the second electrode BxP while maintaining the pattern dimension of the second sub-capacitor structure TSB, thereby increasing the coupling capacitance between the second sub-capacitor structure TSB and the second-type touch capacitor structure TSM. Furthermore, by providing the side branches, the area distribution of the first electrode AxP and the second electrode BxP in the second sub-capacitor structure TSB can be adjusted, thereby adjusting the capacitance variation of the second-type touch capacitor structure TSM, for example, increasing the capacitance variation of the second-type touch capacitor structure TSM.

In the embodiment illustrated in FIG. 12, the grid line distribution density of the second sub-capacitor structure TSB is consistent with that of the first-type touch capacitor structure TSN. On this basis, the first electrode AxP is provided with a side branch FA extending toward the second electrode BxP, and the second electrode BxP is provided with a side branch FB extending toward the first electrode AxP. The side branch of the first electrode AxP and the side branch of the second electrode BxP are arranged alternately and adjacently.

In the embodiment illustrated in FIG. 13, the grid line distribution density of the second sub-capacitor structure TSB is greater than that of the first-type touch capacitor structure TSN. On this basis, the first electrode AxP is provided with a side branch extending toward the second electrode BxP, and the second electrode BxP is provided with a side branch extending toward the first electrode AxP. The side branch of the first electrode AxP and the side branch of the second electrode BxP are arranged alternately. This improves the capacitive coupling between the first electrode AxP and the second electrode BxP, thereby increasing the capacitance variation of the second-type touch capacitor structure TSM. Compared to the embodiment illustrated in FIG. 12, the grid lines in the embodiment illustrated in FIG. 13 are arranged at closer intervals. This allows for more side branches, further enhancing the capacitive coupling between the first electrode AxP and the second electrode BxP, and further increasing the capacitance of the second-type touch capacitor structure TSM.

The embodiments of the present disclosure also conducted simulations to verify this strategy for adding side branches. Specifically, the capacitance of the first-type touch capacitor structure TSN is 0.7042 pf. During touch, the capacitance of the first-type touch capacitor structure TSN is 0.6409 pf, and the change amount of the capacitance of the first-type touch capacitor structure TSN is 0.0633 pf.

In one example, the grid pattern of the first capacitor structure TSM1 is consistent with the grid pattern of the first-type touch capacitor structure TSN, and neither the first electrode AxP nor the second electrode BxP of the first capacitor structure TSM1 has side branches. Therefore, the capacitance of the first capacitor structure TSM1 is 0.4293 pf. During touch, the capacitance of the first capacitor structure TSM1 is 0.3973 pf, and the change amount of the capacitance of the first capacitor structure TSM1 is 0.0320 pf. The capacitance value and change amount of the capacitance of the first capacitor structure TSM1 are significantly different from those of the first-type touch capacitor structure TSN.

In another example, the grid pattern of the first capacitor structure TSM1 is consistent with the grid pattern of the first-type touch capacitor structure TSN. Both the first electrode AxP and the second electrode BxP of the first capacitor structure TSM1 are provided with side branches, and the side branches of the first electrode AxP and the side branches of the second electrode BxP are arranged alternately. The capacitance of the first capacitor structure TSM1 is 0.4730 pf. During touch, the capacitance of the first capacitor structure TSM1 is 0.4384 pf, and the change amount of the capacitance of the first capacitor structure TSM1 is 0.0346 pf. In this case, the differences between the capacitance value and the change amount of the capacitance of the first capacitor structure TSM1 and those of the first-type touch capacitor structure TSN are reduced.

In another example, the grid line distribution density of the second sub-capacitor structure TSB of the first capacitor structure TSM1 is greater than that of the first-type touch capacitor structure TSN, and the grid pattern of the first sub-capacitor structure TSA of the first capacitor structure TSM1 is consistent with the grid pattern of the first-type touch capacitor structure TSN. Both the first electrode AxP and the second electrode BxP of the first capacitor structure TSM1 are provided with side branches, with the side branches of the first electrode AxP and the side branches of the second electrode BxP being arranged alternately. This allows the first capacitor structure TSM1 to have more side branches in the non-display area BB. The capacitance of the first capacitor structure TSM1 is 0.7167 pf. During touch, the capacitance of the first capacitor structure TSM1 is 0.6820 pf, and the change amount of the capacitance of the first capacitor structure TSM1 is 0.0347 pf. In this case, the differences between the capacitance and the change amount of the capacitance of the first capacitor structure TSM1 and those of the first-type touch capacitor structure TSN are further reduced.

In the aforementioned embodiment, in at least one second-type touch capacitor structure TSM, both the first electrode AxP and the second electrode BxP are provided with side branches in the non-display area BB. It will be appreciated that in other embodiments of the present disclosure, in at least one second-type touch capacitor structure TSM, the first electrode AxP may be provided with side branches in the non-display area BB while the second electrode BxP may be not provided with side branches in the non-display area BB, or the second electrode BxP may be provided with side branches in the non-display area BB while the first electrode AxP may be not provided with side branches in the non-display area BB.

In the aforementioned embodiment, in at least one second-type touch capacitor structure TSM, the side branches include a side branch main line and multiple break lines connected to the side branch main line. This reduces the width of the side branches, facilitating the provision of more side branches, thereby further increasing the capacitance of the second-type touch capacitor structure TSM. It is understood that in some other embodiments of the present disclosure, in at least one second-type touch capacitor structure TSM, at least one side branch may also include multiple parallel and interconnected side branch main lines, as well as multiple break lines connected to the side branch main lines at the outer side. In this case, the side branches are wider and arranged in a grid pattern, which can reduce the risk of side branch breakage.

In the above embodiment, in at least one second-type touch capacitor structure TSM, the first electrode AxP is provided with multiple side branches, and the second electrode BxP is provided with multiple side branches. The side branches of the first electrode AxP and the side branches of the second electrode BxP are alternately arranged adjacent to each other, so that the first electrode AxP and the second electrode BxP interdigitate with each other through the side branches. It is understood that in some other embodiments of the present disclosure, at least one side branch of the first electrode AxP may not be adjacent to a side branch of the second electrode BxP, or at least one side branch of the second electrode BxP may not be adjacent to a side branch of the first electrode AxP.

In the aforementioned embodiments, in at least one second-type touch capacitor structure TSM, the side branch includes a side branch main line and a break line connected to the side branch main line. It is understood that in other embodiments of the present disclosure, strategies such as adding break lines in the boundary area or enclosing break lines in the boundary area can also be applied to the side branch to further improve the capacitive coupling of the second-type touch capacitor structure TSM.

For example, in one example, in at least one second-type touch capacitor structure TSM, the boundary area DD of the second-type touch capacitor structure TSM includes a first boundary area and a second boundary area. The first boundary area is adjacent to the side branch, and the remaining portion of the boundary area is the second boundary area. The spacing between the break lines of the second sub-capacitor structure TSB in the first boundary area is smaller than the spacing between the break lines of the second sub-capacitor structure TSB in the second boundary area.

For example, in one embodiment, in at least one second-type touch capacitor structure TSM, at least one side branch includes a side branch main line, a break line connected to the side branch main line, and a side branch closing line that closes at least part of the break lines in the side branch. The side branch closing line is connected to the ends of at least the part of the break lines in at least the side branch. This can improve capacitive coupling between the side branch and adjacent electrodes. It can also form a grid pattern in the side branch, at least partially, or improve the degree of grid patterning, thereby reducing the risk of line breakage. In some examples, the side branch closing line can be a portion of the first closing line or the second closing line.

In the above embodiments, the first capacitor structure TSM1 and the second capacitor structure TSM2 are used as examples to illustrate and describe the possible structures and effects of the second-type touch capacitor structure TSM. It is understood that in other embodiments of the present disclosure, the display panel PNL may include other types of second-type touch capacitor structures TSM.

In the above embodiments, taking the second-type touch capacitor structure TSM employing one of the following strategies: global densification, densification of break lines in the boundary area, closing break lines in the boundary area, and added side branches as an example, to illustrate and describe the structure and effects of the second-type touch capacitor structure TSM. It is understood that in other embodiments of the present disclosure, at least one second-type touch capacitor structure TSM may employ two, three, or four of the above four strategies simultaneously, or employ other strategies that can increase the grid line density of the second sub-capacitor structure TSB.

The present disclosure also provides a display device including any of the display panels described in the above display panel embodiments. The display device can be a smartphone screen, a smartwatch screen, or other type of display device. Since the display device employs any of the display panels described in the above display panel embodiments, it has the same beneficial effects and is not further described herein.

Those skilled in the art will readily recognize other embodiments of the present disclosure after considering the specification and practicing the present disclosure herein. This application is intended to cover any variations, uses, or adaptations of the present disclosure that follow the general principles of the present disclosure and include common knowledge or customary techniques in the art not disclosed herein. The specification and examples are to be considered as exemplary only, with the true scope and spirit of the present disclosure being indicated by the appended claims.

1. A display panel, comprising a display area and a non-display area located at least to one side of the display area;
wherein the display panel comprises a touch sensing layer, the touch sensing layer comprises a plurality of touch positioning areas arranged in an array and touch capacitor structures located within the touch positioning areas; wherein the touch capacitor structures comprise a first-type touch capacitor structure disposed throughout the touch positioning areas and a second-type touch capacitor structure disposed within a portion of the touch positioning areas; electrodes of the touch capacitor structures are grid electrodes; and
the second-type touch capacitor structure comprises a first sub-capacitor structure located in the display area and a second sub-capacitor structure located in the non-display area; wherein a distribution density of grid lines of at least partial area of at least one second sub-capacitor structure is greater than a distribution density of grid lines of the first-type touch capacitor structure.

2. The display panel according to claim 1, wherein in at least one second-type touch capacitor structure, the distribution density of grid lines in each area of the second sub-capacitor structure is greater than the distribution density of grid lines of the first-type touch capacitor structure.

3. The display panel according to claim 2, wherein in the at least one second-type touch capacitor structure, the distribution density of grid lines in each area of the second sub-capacitor structure is 2 to 6 times the distribution density of grid lines of the first-type touch capacitor structure, wherein the distribution density of grid lines is a total length of grid lines per unit area.

4. The display panel according to claim 1, wherein the second-type touch capacitor structure comprises a first electrode and a second electrode disposed in a same layer and adjacent to each other, a boundary area is defined between the first electrode and the second electrode; the first electrode comprises a first edge portion proximate to the boundary area, and the second electrode comprises a second edge portion proximate to the boundary area; and
in at least one second-type touch capacitor structure, a spacing between break lines of at least one of the first edge portion and the second edge portion in the non-display area is smaller than a spacing between the break lines of the at least one of the first edge portion and the second edge portion in the display area.

5. The display panel according to claim 4, wherein in the at least one second-type touch capacitor structure, the second-type touch capacitor structure comprises break line pairs; the break line pairs comprise first break lines located at the first edge portion and second break lines located at the second edge portion, the first break lines and the second break lines extend in a same direction and have adjacent ends; and
wherein a spacing between the break line pairs in the non-display area is smaller than a spacing between the break line pairs in the display area.

6. The display panel according to claim 5, wherein in the at least one second-type touch capacitor structure, an average spacing between the break line pairs in the non-display area is 0.4 to 0.6 times an average spacing between the break line pairs in the display area.

7. The display panel according to claim 1, wherein the second-type touch capacitor structure comprises a first electrode and a second electrode disposed in a same layer and adjacent to each other, a boundary area is defined between the first electrode and the second electrode; the first electrode comprises a first edge portion proximate to the boundary area, and the second electrode comprises a second edge portion proximate to the boundary area;
in at least one second-type touch capacitor structure, a density of break lines of at least one of the first edge portion and the second edge portion in the non-display area is larger than a density of the break lines of the at least one of the first edge portion and the second edge portion in the display area;
the density of the break lines of the first edge portion in the non-display area refers to a ratio of a number of the break lines of the first edge portion in the non-display area to a length of a portion of the boundary area located in the non-display area;
the density of the break lines of the second edge portion in the non-display area refers to a ratio of a number of the break lines of the second edge portion in the non-display area to the length of the portion of the boundary area located in the non-display area;
the density of the break lines of the first edge portion in the display area refers to a ratio of a number of the break lines of the first edge portion in the display area to a length of a portion of the boundary area located in the display area; and
the density of the break lines of the second edge portion in the display area refers to a ratio of a number of the break lines of the second edge portion in the display area to the length of the portion of the boundary area located in the display area.

8. The display panel according to claim 1, wherein the second-type touch capacitor structure comprises a first electrode and a second electrode disposed in a same layer and adjacent to each other, a boundary area is defined between the first electrode and the second electrode; the first electrode comprises a first edge portion proximate to the boundary area, and the second electrode comprises a second edge portion proximate to the boundary area; and
in at least one second-type touch capacitor structure, at least one of the first edge portion and the second edge portion comprises a closed line located in the non-display area, and the closed line is connected to ends of at least some of the break lines.

9. The display panel according to claim 8, wherein in the at least one second-type touch capacitor structure, both the first edge portion and the second edge portion have closed lines; the closed lines of the first edge portion and the second edge portion are parallel and adjacent to each other.

10. The display panel according to claim 1, wherein the second-type touch capacitor structure comprises a first electrode and a second electrode disposed in a same layer and adjacent to each other;
in at least one second-type touch capacitor structure, the first electrode comprises a main body and at least one side branch connected to the main body, a width of the side branch is smaller than a width of the main body; the side branch of the first electrode is disposed adjacent to the second electrode, and the side branch of the first electrode is located in the non-display area; and/or the second electrode comprises a main body and at least one side branch connected to the main body, a width of the side branch is smaller than a width of the main body; the side branch of the second electrode is disposed adjacent to the first electrode, and the side branch of the second electrode is located in the non-display area.

11. The display panel according to claim 10, wherein in the at least one second-type touch capacitor structure, the first electrode comprises multiple side branches, and the second electrode comprises multiple side branches;
the side branches of the first electrode and the side branches of the second electrode are disposed alternately and adjacently.

12. The display panel according to claim 11, wherein the distribution density of the grid lines of the second sub-capacitor structure is greater than the distribution density of the grid lines of the first-type touch capacitor structure.

13. The display panel according to claim 10, wherein in the at least one second-type touch capacitor structure, the side branch comprises a side branch main line and multiple break lines connected to the side branch main line.

14. The display panel according to claim 1, wherein the touch sensing layer is provided with a plurality of first touch signal channels arranged sequentially along a first direction and a plurality of second touch signal channels arranged sequentially along a second direction, the first direction and the second direction is arranged intersecting;
one of the first touch signal channels and one of the second touch signal channels pass through any touch positioning area; the touch capacitor structure comprises a first electrode located in the first touch signal channel and a second electrode located in the second touch signal channel; the first electrode and the second electrode are both grid electrodes composed of grid lines and are provided in a same layer.

15. The display panel according to claim 14, wherein at least one of the first touch signal channels and the second touch signal channels comprises a channel body and an auxiliary electrode, the auxiliary electrode is surrounded by the channel body and separated from the channel body.

16. The display panel according to claim 1, wherein a distribution density of grid lines of the first sub-capacitor structure is consistent with the distribution density of the grid lines of the first-type touch capacitor structure.

17. The display panel according to claim 1, wherein the non-display area comprises at least one of a first non-display area and a second non-display area;
wherein the first non-display area surrounds the display area; and the second non-display area is partially or completely surrounded by the display area.

18. The display panel according to claim 17, wherein the display area has a curved top corner, and the second-type touch capacitor structure comprises a first capacitor structure; and the first capacitor structure spans an edge of the curved top corner of the display area.

19. The display panel according to claim 17, wherein a via hole is provided in the second non-display area; the second-type touch capacitor structure comprises a second capacitor structure at least partially located in the second non-display area; and a second sub-capacitor structure of the second capacitor structure is a grid electrode composed of grid lines.

20. A display device comprising the display panel according to claim 1.
